(19) United States
(12) Patent Application Publication
(10) Pub. No.: US 2017/0250059 A1
(43) Pub. Date: Aug. 31, 2017

(54) METHODS AND APPARATUSES FOR CONTROLLING PLASMA PROPERTIES BY CONTROLLING CONDUCTANCE BETWEEN SUB-CHAMBERS OF A PLASMA PROCESSING CHAMBER

(71) Applicant: Lam Research Corporation, Fremont, CA (US)

(72) Inventor: Andreas Fischer, Castro Valley, CA (US)

(21) Appl. No.: 15/594,572

(22) Filed: May 13, 2017

Related U.S. Application Data
(62) Division of application No. 13/339,312, filed on Dec. 28, 2011.

(51) Int. Cl. H01J 37/32

(52) U.S. Cl. CPC H01J 37/32623; H01J 37/32899; H01J 37/32449; H01J 37/32091

(57) ABSTRACT

A plasma processing system having at least one processing chamber comprising at least two sub-chambers is provided. The two plasma sub-chambers are in plasma flow or gas flow communication through a passage, which is controlled by a gate. The gate may be operated to allow plasma migration between the two sub-chambers to occur at different conductance rates. In one example, the gate comprises two plates with openings through the plates. At least one of the plates may be rotatable relative to the other plates to govern the conductance rate of the plasma from one sub-chamber to the other sub-chamber.

### CROSS-REFERENCE TO RELATED APPLICATION

This application is a divisional of and claims priority to U.S. application Ser. No. 13/339,312, titled “METHODS AND APPARATUSES FOR CONTROLLING PLASMA PROPERTIES BY CONTROLLING CONDUCTANCE BETWEEN SUB-CHAMBERS OF A PLASMA PROCESSING CHAMBER,” filed Dec. 28, 2011, all of which is incorporated herein by this reference and for all purposes.

### BACKGROUND OF THE INVENTION

Plasma has long been employed for processing substrates (e.g., wafers, flat panel displays, liquid crystal displays, etc.) into electronic devices (e.g., integrated circuit dies) for incorporation into a variety of electronic products (e.g., smart phones, computers, etc.).

In plasma processing, a plasma processing system having one or more plasma processing chambers may be employed to process one or more substrates. In each chamber, plasma generation may employ capacitively coupled plasma technology, inductively coupled plasma technology, electron-cyclotron technology, microwave technology, etc.

During the processing of a wafer, for example, plasma is generated from the supplied reactant gases to etch, deposit, or otherwise process exposed areas of the wafer surface (which may include the planar surface and/or the bevel edge of the wafer). During processing, various input parameters such as RF power, RF bias potential, DC bias potential, reactant gas flow, exhaust gas flow, etc., may vary to obtain the desired plasma for each step or sub-step of the process. When the input parameters are changed, the plasma characteristics (e.g., ion flux, radical flux, sheath thickness, etc.) are changed correspondingly and complex processing using plasmas of varying characteristics is rendered possible.

There is a limit, however, on how much the plasma characteristics may be changed in any given chamber. This is due, in part, to the geometry of each chamber, the type of electrodes employed, the range of parameters that can be varied for a particular chamber, the type of plasma generation technology employed (e.g., capacitive versus inductive versus ECR versus microwave).

In the past, it has been possible to manipulate input parameters of the chamber to obtain the desired process condition window to process the substrate. As technology progresses, however, processing requirements have become more stringent, with customers specifying for example smaller device geometries, more complex devices, more tightly controlled etch profiles, higher wafer throughput, etc. These processing requirements demand process condition windows that exceed what current processing chambers are capable of providing.

Given these concerns, embodiments of the invention offer different, in-situ apparatuses and methods to meet tomorrow's stringent processing requirements.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, in accordance with an embodiment of the invention, a conceptual drawing of a plasma processing chamber having two plasma sub-chambers interconnected via a passage that is controlled by a gate.

FIG. 2 shows, in accordance with an embodiment of the invention, a simplified cross-section view of a more detailed implementation of a processing chamber having multiple sub-chambers with their plasma mixing controlled by a gate.

FIG. 3A and 3B show, in accordance with an embodiment of the invention, top-down views of an implementation of a gate employing at least one rotatable plate.

FIGS. 4A and 4B illustrate the example wherein the two plates of a gate are linearly translated relative to one another using an appropriate actuator

FIG. 5 shows, in accordance with an embodiment of the invention, a method for implementing the plasma mixing gate described in various embodiments of the invention.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described hereinbelow, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to improved methods and apparatuses for processing a substrate using plasma. In one or more embodiments, a plasma processing system having at least one processing chamber comprising at least two sub-chambers is provided. The two sub-chambers are in plasma flow or gas flow communication through a passage, which is controlled by a gate. Each sub-chamber may generate its own plasma, using any desired plasma generation technology (e.g., inductively coupled, capacitively coupled, ECR, microwave, etc.) and any desired set of input parameters. Although the sub-chambers may employ the same plasma generation technology if desired, there is no requirement that the sub-chambers must use the same plasma generation technology. Thus the plasma generated in each of the sub-chambers may differ from one another.

For example, one sub-chamber may employ one type of plasma generation technology and the other sub-chamber may employ another type of plasma generation technology. As another example, one sub-chamber may employ a given type of plasma generation technology (such as capacitively coupled) and the other sub-chamber may employ the same type of plasma generation technology, albeit with different input parameters (e.g., different RF frequency, different reactant gas(es), different bias power, different process pressure, different sub-chamber design and/or different RF power, etc.).

The gate in between the sub-chambers is designed to selectively configure the passage to operate in either a first state or a second state (first passage condition or second passage condition respectively). In the first state, plasma from one sub-chamber is allowed to migrate or flow into the other sub-chamber via pressure differential or by active pumping. The sub-chamber where the two plasmas are mixed is, in one or more embodiments, the sub-chamber where the substrate is disposed for processing. In the second state, the plasmas from the different sub-chambers are isolated from one another such that no significant or zero migration occurs.

In one or more embodiments, the gate may alternate between the two states in cycles, resulting in a pulsing or periodically varying plasma in the sub-chamber where plasma mixing occurs to process the substrate. In one or more embodiments, such pulsing or periodically varying plasma may occur once every so many seconds, or many times per second or many dozen times per second or many hundred times per second or many thousand times per second. The pulsing or varying plasma may also occur in an asynchronous manner, with the gate controlled by software, for example, to match processing requirements in a sub-step of the recipe or from sub-step to sub-step of a recipe (the recipe may be thought of as involving multiple sub-steps in this example).

In one or more embodiments, the gate that controls the passage between the sub-chambers is implemented by two moving plates having openings therein. The two plates may move rotationally relative to one another (for example around a common rotational axis or on individual rotational axes) such that when their openings line up, plasma migration from one sub-chamber to another sub-chamber is permitted. When their openings are not lined up and one plate's openings are blocked by the solid portion of the other plate, plasma and process gas migration from one sub-chamber to another sub-chamber are essentially inhibited or not allowed. When their openings are partially lined up, reduced plasma and process gas migration are achieved with the volume of plasma allowed to migrate controlled by the relative position of the two plates. The separation between the plates is preferably kept as small as possible to achieve a semi-seal when the openings are not lined up. The separation between the plates is typically in the order of 0.1 mm, preferably less, and is limited by the machining tolerances in the manufacturing processes of both plates and the tolerances of the plates bearings.

In one or more embodiments, one plate is stationary while the other plate is rotated. In a preferred embodiment, the stationary plate is the plate that is the closer (relative to the other plate) to the substrate to reduce possible particulate contamination. In one or more embodiments, the openings in one plate is wedge-shaped and the opening in the other plate is rectangular shaped (referred to herein as slit-shaped) or contains at least a slit-shaped portion. Alternatively both plates may be rotated in different directions or in the same direction, albeit at different rotational speeds, in order to better distribute the migrating plasma evenly in the sub-chamber where plasma mixing occurs. In one or more embodiments, the openings in one or both of the plates may be round holes.

In one or more embodiments, one plate is stationary while the other plate is linearly translated back and forth in its own plane. In a preferred embodiment, the stationary plate is the plate that is the closer (relative to the other plate) to the substrate to reduce possible particulate contamination. Alternatively both plates may be linearly translated out-of-synch relative to one another to operate the passage in different states. In one or more embodiments, the bearings of the plates may be disposed at their edges and may be captured to reduce the risk of particle shedding onto the wafer.

As mentioned, plasma migration (expansion) may occur when the gate is opened between the two sub-chambers due to a pressure differential or active pumping. In some cases, it may be desirable to limit plasma migration to only one direction (e.g., from the top sub-chamber to the bottom sub-chamber but not from the bottom sub-chamber to the top sub-chamber). In this case, the size of the openings in one or both of the plates may be used to advantage. For example, the size of the openings in one or both of the plates may be sized such that each opening is larger than twice the sheath thickness of the plasma of the first sub-chamber but less than twice the sheath thickness of the plasma of the second sub-chamber. In this case, even when the openings are aligned, the plasma from the second sub-chamber cannot migrate to the first sub-chamber through the passage between the sub-chambers because the size of one or both of the plate openings is smaller than twice the sheath thickness of the plasma of the second sub-chamber. This is a scenario in which the plasma of the second sub-chamber remains ‘confined’ to the second sub chamber, even though the gate has fully opened, whereas plasma of the first sub-chamber is permitted to advance through the gate into the second sub-chamber.

In one or more embodiments, one plate may be made from a conductive material (such as aluminum or silicon or a suitable conductive material that is plasma compatible or plasma resistant) to facilitate grounding while the other plate may be made from an insulating material (such as quartz). However, it is possible for both plates to be grounded and/or both may be made from the same material. Grounding of at least one plate is necessary to mutually shield each sub-chamber from the direct influence of the RF fields of the respective other chamber.

Although two sub-chambers are discussed, it is possible that more than two sub-chambers may be interconnected through such passages to achieve the advantages of working with multiple different types of plasmas of widely varying plasma characteristics while the substrate remains in-situ in one of the sub-chambers. For example, a three sub-chamber arrangement may be implemented whereby the substrate-bearing plasma sub-chamber may be coupled to two other plasma sub-chambers, with the coupling passages controlled by gates (either individually or in tandem) in the manner discussed herein.

The features and advantages of embodiments of the invention may be better understood with reference to the figures and discussions that follow.

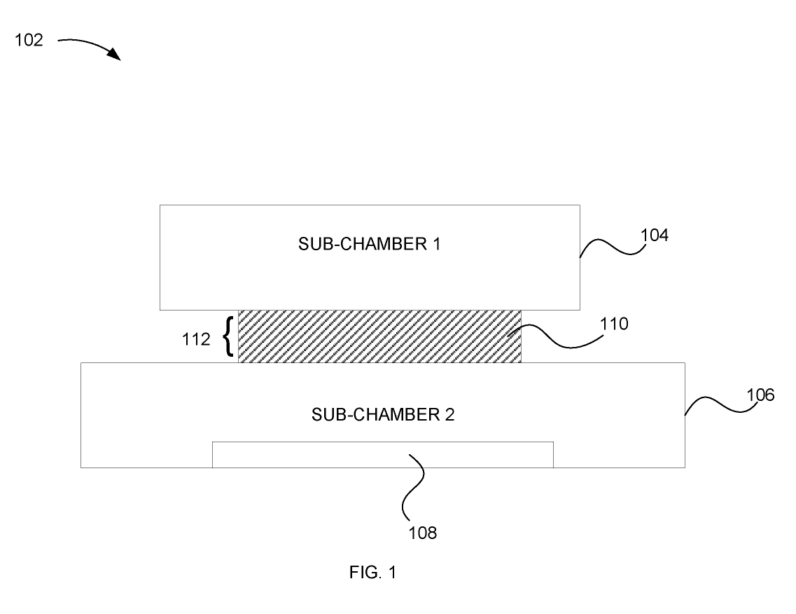

FIG. 1 shows, in accordance with an embodiment of the invention, a conceptual drawing of a plasma processing chamber 102 having a plasma sub-chamber 104 and a plasma sub-chamber 106. A substrate 108 is shown disposed in sub-chamber 106 for processing. Sub-chamber 104 is in gas flow or plasma flow communication with sub-chamber 106 via a passage 112. Passage 112 is controlled by a gate mechanism shown by reference 110 to operate passage 112 in a first state or a second state. In the first state, plasma from sub-chamber 104 is permitted by gate 110 to migrate into sub-chamber 106 with a first conductance rate. In the second state, plasma from sub-chamber 104 is permitted by gate 110 to migrate into sub-chamber 106 with a second conductance rate different from the first conductance rate. The second conductance rate may be, for example, zero or very close to zero while the first conductance rate may reflect a substantially more significant quantity of plasma migrating into sub-chamber 106.

Each of sub-chambers 104 and 106 may generate its own plasma using its own plasma generating source and/or plasma generating technology and/or its own set of input parameter values. By controlling the mixing of the plasmas from the two sub-chambers, the plasma that is obtainable to process (e.g., etch or deposit) the substrate is substantially different from the plasma that is obtainable from sub-chamber 106 alone.

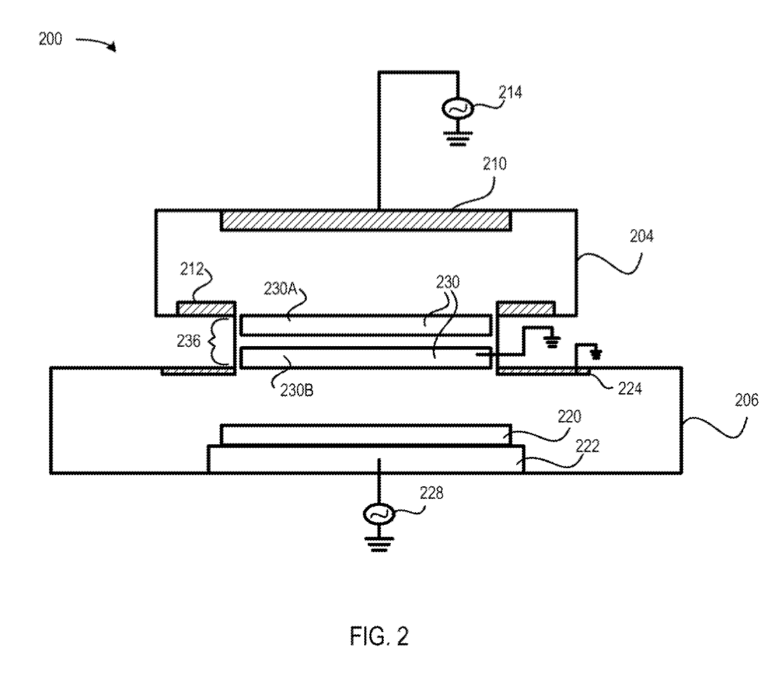

FIG. 2 shows, in accordance with an embodiment of the invention, a simplified cross-section view of a more detailed implementation of a processing chamber having multiple sub-chambers with their plasma mixing controlled by a gate. In FIG. 2, a plasma chamber 200 having a sub-chamber 204 and a sub-chamber 206 is shown. Sub-chamber 204 represents in the example of FIG. 2 a capacitively coupled plasma sub-chamber having two electrodes 210 and 212, with electrode 210 being energized by an RF source 214 and electrode 212 grounded. RF source 214 may provide one or more RF signals to electrode 210.

A substrate 220 is disposed on a work piece holder or chuck 222 in sub-chamber 206 for processing. In the example of FIG. 2, sub-chamber 206 is also a capacitively coupled plasma sub-chamber and produces plasma using an RF-powered electrode/chuck 222 and a grounded electrode 224. RF-powered electrode 222 receives RF energy from an RF source 228. For simplicity, the gas feeds into sub-chambers 204 and 206 are omitted from the drawings, as are the exhaust fans and other monitoring and/or substrate loading components.

A gate mechanism 230 comprising plates 230A and 230B is shown. Gate mechanism 230 controls the migration of plasma from sub-chamber 204 into sub-chamber 206 through passage 236. As mentioned earlier, the plasma produced in sub-chamber 204 may be permitted to migrate into sub-chamber 206 to mix with the plasma produced in sub-chamber 206 to process substrate 220. In one or more embodiments, the mixing results in any desired ratio of the plasmas produced in sub-chamber 206 and sub-chamber 204.

For example, the mixing may produce a plasma that is 80% from sub-chamber 204 and 20% from sub-chamber 206. As another example, the mixing may produce a plasma that is 50% from sub-chamber 204 and 50% from sub-chamber 206. As another example, the mixing may produce a plasma that is 100% from sub-chamber 204 and 0% from sub-chamber 206 (which implies that sub-chamber 206 does not produce its own plasma during that mixing duration). As another example, the mixing may produce a plasma that is 0% from sub-chamber 204 and 100% from sub-chamber 206 (which implies that sub-chamber 204 does not produce its own plasma during that mixing duration). The resulting plasma may have varying ratios of the two plasmas while the substrate remains in-situ in sub-chamber 206 to allow the substrate to be etched with different combinations of plasmas from different sub-chambers. The plasma in sub-chamber 206 may be pulsed or varied synchronously or asynchronously with one or more of the other input parameters (of one or both of the sub-chambers) using different plasma ratios as desired. Alternatively or additionally, the plasma in sub-chamber 206 may be pulsed or varied periodically or non-periodically using different plasma ratios as desired.

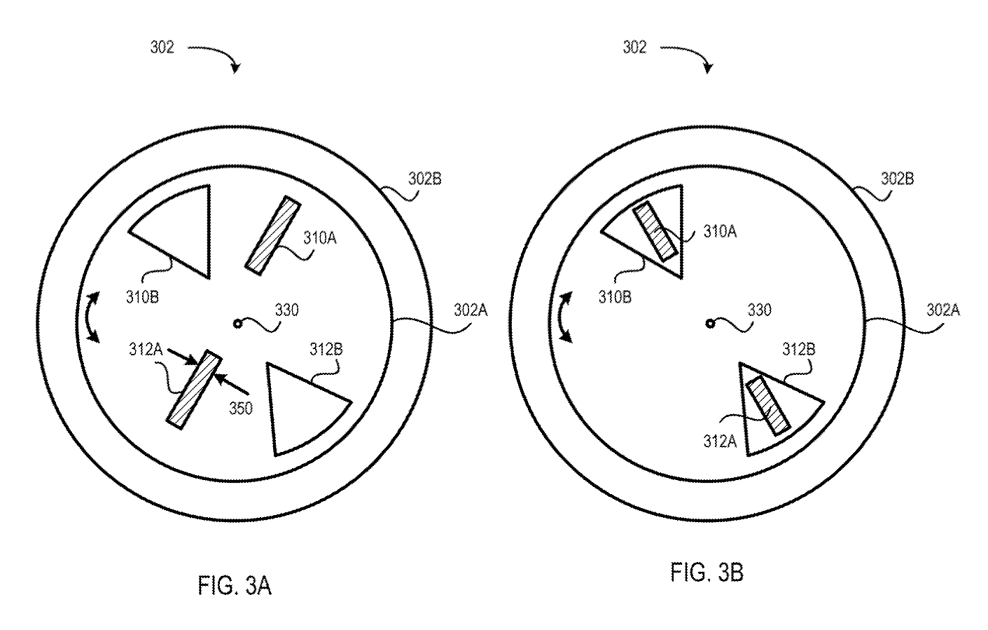

FIG. 3A and 3B show, in accordance with an embodiment of the invention, top-down views of an implementation of gate 230 of FIG. 2. In the embodiment of FIG. 3A and FIG. 3B, gate 302 is implemented by two plates 302A and 302B. In the top-down view of FIG. 3A, plate 302A is drawn smaller than plate 302B to render the concept easier to explain. However, these two plates may also be equal in size or plate 302A may be larger than plate 302B if desired.

Plate 302A, being the top plate in FIG. 3A, is provided with two slit-shaped openings 310A and 312A. Plate 302B, being the bottom plate in FIG. 3B, is provided with two wedge-shaped openings 310B and 312B. Although only two slit-shaped openings and two wedge-shaped openings are provided, there may be many more openings provided in the two plates to facilitate more uniform gas distribution and migration. Plates 302A and 302B rotate relative to one another around a common rotational axis 330 using an appropriate actuator (which may be electromagnetic, electrical, air-actuated, hydraulically actuated, etc.).

In the example of FIGS. 3A and 3B, plate 302B is stationary and is closer to the substrate while plate 302A rotates. However, it is possible to rotate both plates in different directions or in the same direction albeit at different rotational rates as desired.

In FIG. 3A, the openings in the two plates are not aligned and thus plasma and process gas flow are inhibited through the plates of the gate. In FIG. 3B, the openings are aligned and thus plasma and process gas flow are permitted. Note that the cross-section width 350 of the slits may be dimensioned such that plasma flow is permitted in only one direction as discussed earlier.

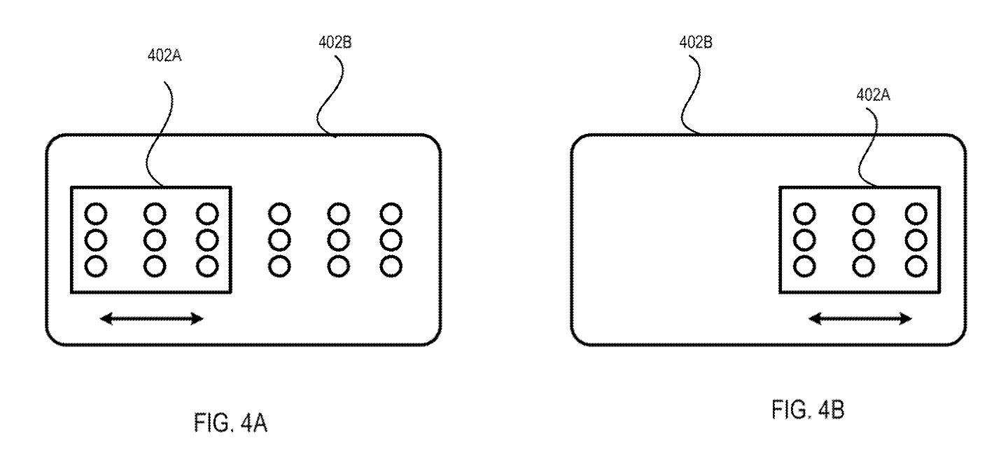

FIGS. 4A and 4B illustrate the example wherein the two plates 402A and 402B of a gate are linearly translated relative to one another using an appropriate actuator (which may be electromagnetic, electrical, air-actuated, hydraulically actuated, etc.). When their openings line up, either partially or completely, plasma flow is permitted between the sub-chambers. When their openings do not line up, plasma flow is inhibited between the sub-chambers.

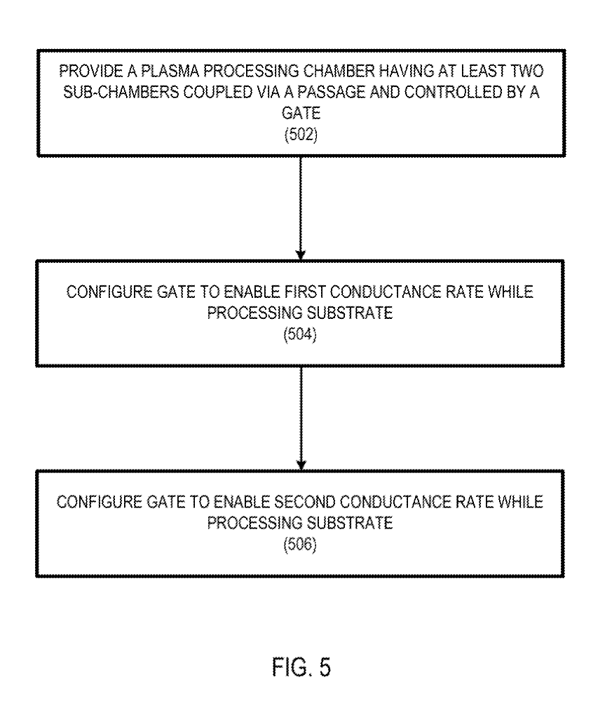

FIG. 5 shows, in accordance with an embodiment of the invention, a method for implementing the plasma mixing gate described in various embodiments of the invention. In step 502, a plasma processing chamber having at least two plasma sub-chambers is provided. The sub-chambers are in plasma communication with one another, with the conductance rate between the sub-chambers governed by a gate mechanism. In step 504, the gate mechanism is configured such that a first plasma conductance rate exists between the two sub-chambers while the substrate is processed in one of the sub-chambers. In step 506, the gate mechanism is configured such that a second plasma conductance rate exists between the two sub-chambers while the substrate is processed in-situ in the same sub-chamber. As mentioned, one of the two plasma conductance rates may be zero if desired. Step 504 and 506 may alternate in a periodic, non-periodic, synchronous, or asynchronous (with respect to another parameter in the sub-chamber) while processing the substrate.

As can be appreciated from the foregoing, embodiments of the invention advantageously result in mixed plasma having a wide range of plasma characteristics to meet tomorrow's processing needs. The variety of plasmas obtained by mixing plasmas from different sub-chambers greatly exceeds the variety of plasmas obtainable by any one of the sub-chambers alone. Since each sub-chamber generates its own plasma and has its own plasma pre-generated prior to mixing, little time is wasted when switching from one plasma regime to another plasma regime in the sub-chamber that holds the substrate. These features widen the process condition window and improves wafer throughput.

While this invention has been described in terms of several preferred embodiments, there are alterations, permutations, and equivalents, which fall within the scope of this invention. Although various examples are provided herein, it is intended that these examples be illustrative and not limiting with respect to the invention. Also, the title and summary are provided herein for convenience and should not be used to construe the scope of the claims herein. Further, the abstract is written in a highly abbreviated form and is provided herein for convenience and thus should not be employed to construe or limit the overall invention, which is expressed in the claims. If the term “set” is employed herein, such term is intended to have its commonly understood mathematical meaning to cover zero, one, or more than one member. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. A method for processing a substrate using plasma in a plasma processing system having at least one plasma processing chamber, comprising:
providing a first sub-chamber having a first plasma generation means for generating first plasma having first plasma characteristics;
providing a second sub-chamber having a second plasma generation means for generating second plasma having second plasma characteristics different from said first plasma characteristics, said second sub-chamber having a work piece holder for supporting said substrate in said second sub-chamber during said processing, wherein a passage interconnects said first sub-chamber and said second sub-chamber, said passage being controlled by a gate for selectively configuring said passage to operate in accordance with at least a first passage condition and a second passage condition, said first passage condition permitting a first conductance rate of said first plasma into said second sub-chamber, said second passage condition permitting a second conductance rate of said first plasma into said second sub-chamber, whereby said first conductance rate is different from said second conductance rate;
processing said substrate in said second sub-chamber while said gate is operated to permit said first conductance rate; and
processing said substrate in said second sub-chamber while said gate is operated to permit said second conductance rate.

2. The method of claim 1 wherein said first conductance rate is zero.

3. The method of claim 1 wherein said gate comprises a first plate and a second plate, said first plate and said second plate are movable relative to one another, said first plate having first openings disposed through said first plate, said second plate having second openings disposed through said second plate, said method further comprising rotating at least one of said first plate and said second plate to switch from said processing using said first conductance rate to said processing using said second conductance rate.

4. The method of claim 3 wherein at least one of said first openings and second openings has a cross-sectional dimension that is greater than twice the sheath thickness of said first plasma but less than twice the sheath thickness of said second plasma.

5. The method of claim 1 wherein a pressure inside said first sub-chamber during said processing is greater than a pressure inside said second sub-chamber during at least a portion of said processing.

6. The method of claim 3 wherein said first plate and said second plate are translationally movable relative to one another in a linear direction, said method further comprising translating at least one of said first plate and said second plate to switch from said processing using said first conductance rate to said processing using said second conductance rate.
